(19) United States
(12) Patent Application Publication
(10) Pub. No.: US 2007/0063213 A1
(43) Pub. Date: Mar. 22, 2007

(54) LED package

(75) Inventors: Hsiang-Cheng Hsieh, Hsin-Chu (TW); Teng-Huei Huang, Hsin-Chu (TW); Wen-Lung Su, Hsin-Chu (TW)

Correspondence Address: TROXELL LAW OFFICE PLLC, SUITE 1404, 5205 LEESBURG PIKE, FALLS CHURCH, VA, 22041, US

(73) Assignee: Lighthouse Technology Co., Ltd.

(21) Appl. No.: 11/230,574

(22) Filed: Sep. 21, 2005

(51) Int. Cl. H01L 33/00

(52) U.S. Cl. 257/99; 257/100; 257/E33.075

(57) ABSTRACT

A package allowing agile deployment of the location of each LED chip includes a heat slug to secure multiple LED chips, two lead frames, a conducting area extending along the edge of the heat slug, and a non-conductive material that connects the heat slug and the lead frame for those multiple LED chips to connect to the conducting area by means of a gold wire without being subject to the presence of the lead frame.

### BACKGROUND OF THE INVENTION

(a) Field of the Invention

The present invention is related to a package, and more particularly to a surface mount device (SMD) package adaptable to multiple light emitting diode (LED) chips.

(b) Description of the Prior Art

The LED manufacturing cost has been significantly reduced thanks to continuous improvement of the LED process technologies. The LED therefore gradually exits the conventional lamps in the application areas of Xmas light, flashlight, and traffic light while taking up the LED market at a rapid expansion speed. When functioning as a backlight source for a liquid crystal display (LCD) or a lighting fixture, the LED consumes massive power, and more waste heat is generated when multiple LEDs are lighted at the same time. The waste heat from LEDs though is not at a temperature as high as that does by a tungsten filament lamp, it may prevent related circuits from providing normal functions or compromise the service life or the LEDs. The waste heat generated by multiple LEDs working collectively is not an issue that can be ignored.

As illustrated in FIG. 1 of the accompanying drawings, an LED package of the prior art is essentially comprised of a heat sink 11 as the basic material; a printed circuit board (PCB) layer 12 with a specific circuit layout is disposed on top of the heat sink 11 and distributed with gold wires 22 or aluminum wires to respectively connected to pads 121, 122 before being bound with an encapsulating material 23 to constitute an LED 2 together with a chip 21 disposed further on top of the encapsulating material 23. Wherein, multiple LEDs 2 are interconnected to one another through the circuit on the PCB layer 12, and subject to an externally control/drive circuit also through the PCB layer 12.

Usually the PCB layer 12 is formed in two ways. One method involves having first developed an oxidization layer on top of the heat sink followed with a PCB layer with copper circuit for the PCB layer to contact the heat sink through the oxidization layer; and another method involves having coated at the bottom of the heat sink a heat conductive material and a metal material with high conductivity (e.g., copper), then followed with the circuit production including pattern transfer, exposure, development, and etching processes that are generally known to the LED manufacturing industry to provide multiple pairs of pad on the metal material, i.e., the PCB layer. However, in either way, it is blamed for complicated manufacturing process, comparatively higher nonconformity rate, and difficulties in providing specific circuit for the circuit layout in coping with the location of the chip.

### SUMMARY OF THE INVENTION

The primary purpose of the present invention is to provide a simple structure secured on the heat slug for the connection between the LED and the lead frame to achieve effective heat dissipation purpose.

To achieve the purpose, the package of the present invention includes a heat slug to secure multiple LEDs, two lead frames with conducting area extending along the edge of the heat slug, and an encapsulating material constituting the connection between the heat slug and the lead frames. Multiple LED chips are connected to the conducting area by means of gold wire so to free each LED chip from the restriction imposed by the lead frames. Accordingly, the location of each LED chip may be deployed with much more flexibility.

### BRIEF DESCRIPTION OF THE DRAWINGS

FIG. 1 is a schematic view showing a structure of a LED package of the prior art.

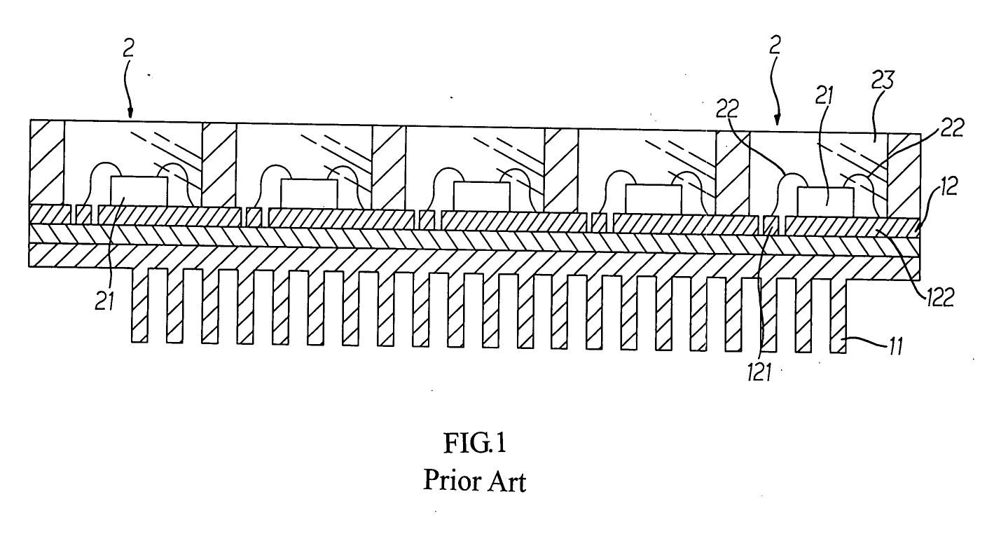

FIG. 2 is a perspective view of a structure of heat slug and lead frame in a preferred embodiment of the present invention.

FIG. 3 is a schematic view showing a structure of heat slug and lead frame in the preferred embodiment of the present invention.

FIG. 4 is a schematic view showing a structure of an LED package of the preferred embodiment of the present invention.

FIG. 5 is an exploded view showing the structure of the LED package of the preferred embodiment of the present invention.

FIG. 6 is a view showing the status of the light radiation performance of the LED package of the preferred embodiment of the present invention.

FIG. 7 is a schematic view showing an arrangement of multiple LEDs in the heat slug of another preferred embodiment of the present invention.

FIG. 8 is a schematic view showing a structure of the heat slug and a high power single chip LED of the present invention.

### DETAILED DESCRIPTION OF THE PREFERRED EMBODIMENTS

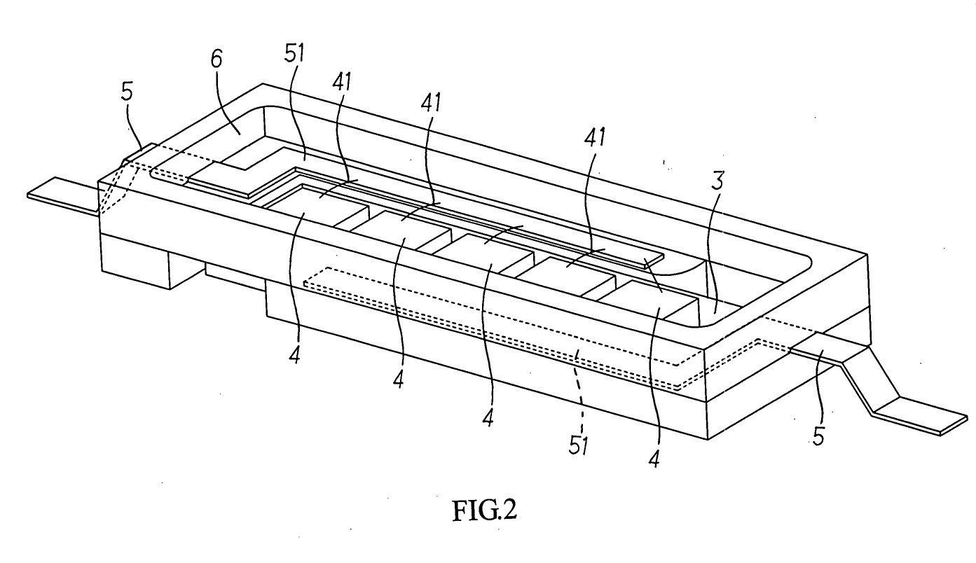

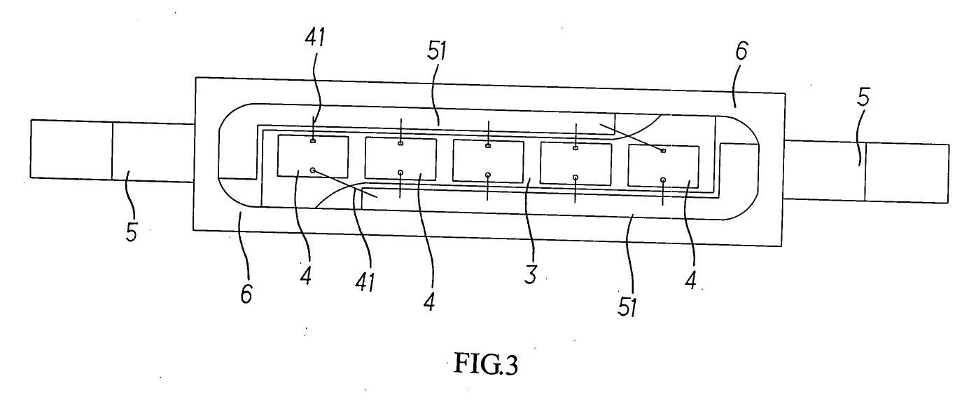

A light emitting diode package of the present invention as illustrated in FIGS. 2 and 3 includes a heat slug 3 related to an aluminum or copper substrate for the placement of multiple SMD LEDs 4 with each LED 4 selectively containing one or a plurality of light emitting chip.

Two lead frames 5 bound to both shorter sides of the heat slug 3 by means of a non-conductive material 6 with each lead frame 5 extending for a conductive area 51 respectively along both sides of the heat slug 3 in the direction of the arrangement of those LEDs 4.

The non-conductive material 6 constituting the connection between the heat slug 3 and both lead frames 5 is made in a form of a frame surrounding the sides of the heat slug 3.

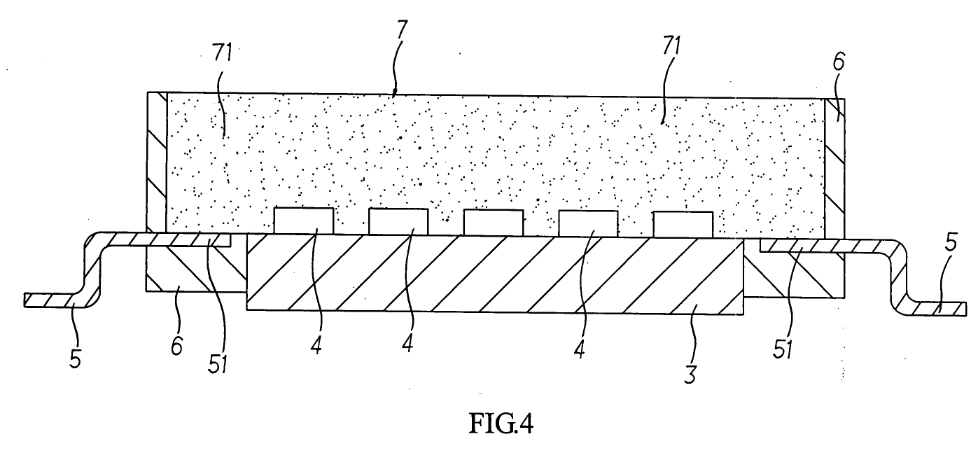

When assembled, those multiple SMD LEDs 4 are placed on the heat slug 3 and plated with a gold wire 41 to respectively connect to the conductive areas 51 on both sides. The heat slug 3 is then covered up with an encapsulating material 7, and the encapsulating material 7 is accommodated within the frame formed by the non-conductive material 6 to complete an integral LED package as illustrated in FIG. 4. Depending on the light source effects to be produced as desired, different light emitting chips are assigned to those multiple SMD LEDs. Furthermore, a phosphor 71 is mixed with the encapsulating material 7 to form a specific light color by incorporating the light emitted through the phosphor 71 from the LED and the light wavelength of the phosphor 71.

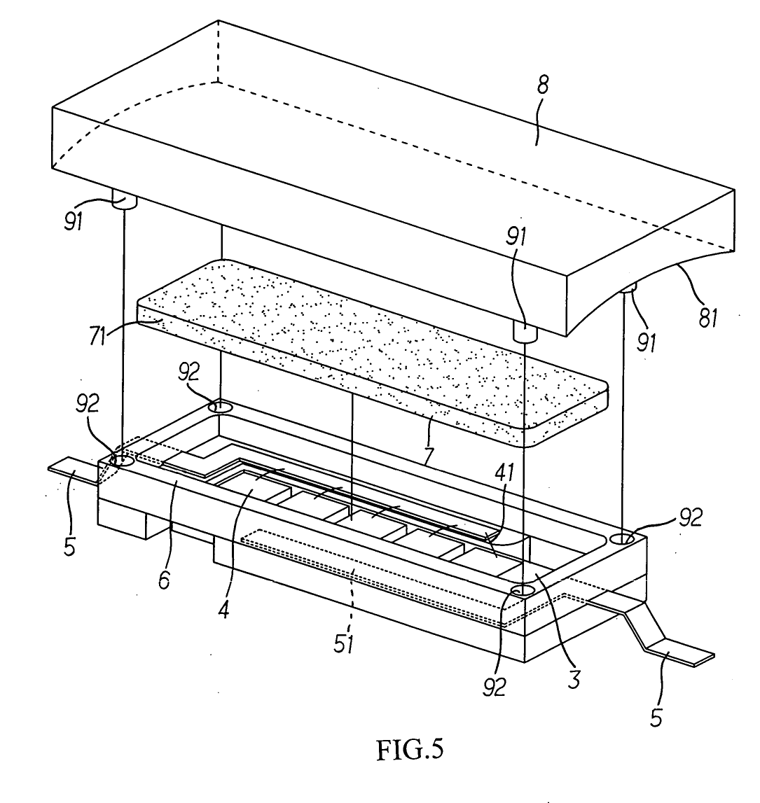

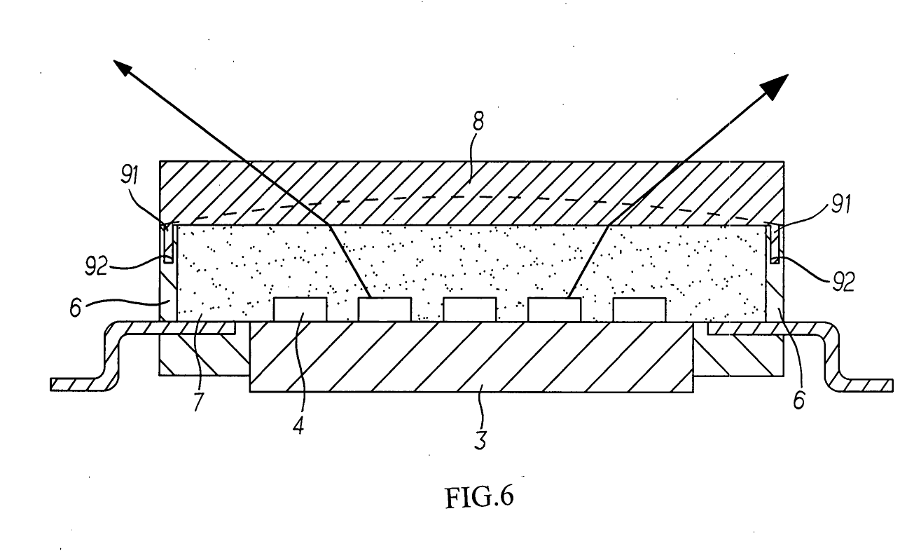

Of course, a lens 8 may be further provided above the encapsulating material 7 to change the traveling route of the light emitted from the LED 4. As illustrated in FIGS. 5 and 6, a refraction plane 81 is defined in the traveling route of the LED by the lens 8, and any light passing through the refraction plane 81 gives diffusion effect to increase the coverage of the light diffusion. Meanwhile, a pin 91 is formed between where both of the lens 8 and the non-conductive material 6 contact each other. A recess 92 to engage the pin 91 is disposed on the non-conductive material 6 so to secure the lens 8 at where above the non-conductive material 6.

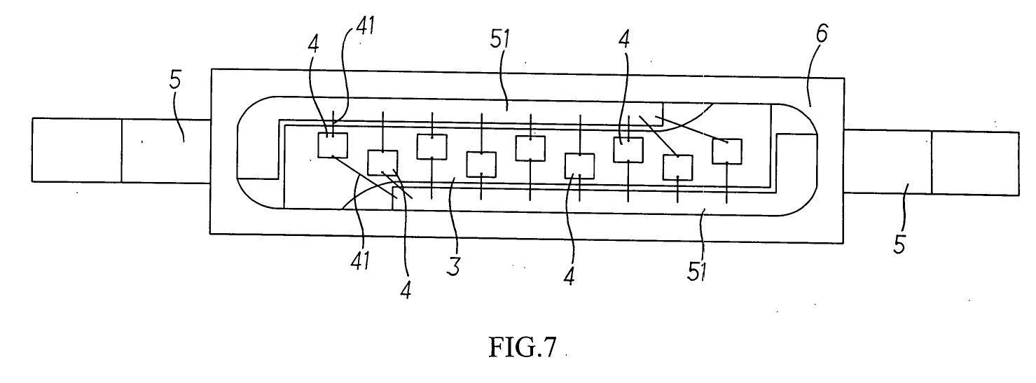

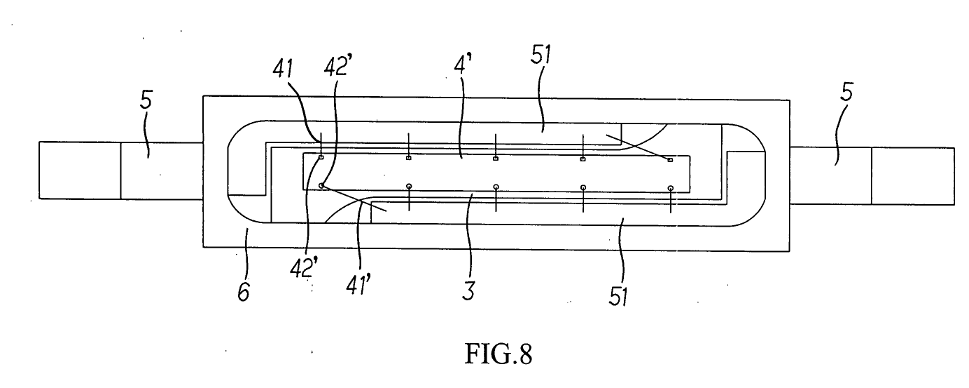

Those SMD LEDs 4 inside the heat slug 3 may be arranged in a linear fashion as illustrated in FIG. 3, or in an alternative fashion as illustrated in FIG. 7. A high power LED 4′ may be placed in the heat slug 3 as illustrated in FIG. 8 to have a single chip disposed with multiple bonding pads 42′ to achieve the connection between each bonding pad 42′ and the conductive area 51 on both sides by means of a gold wire 41′.

The present invention provides the following advantages:
1. Whereas the gold wire is used for those multiple SMD LEDs to connect the conductive area, the gold wire connection location for each LED is free from the restriction imposed by the lead frames. Accordingly, multiple options are available for the deployment of the location for each LED.
2. Whereas each LED is secured to the heat slug made of aluminum or copper substrate, it provides effective thermal function with high heat dissipation property.
3. Whereas LEDs may be adapted with various types of light emitting chips depending on the light source effect to be produced as desired in the form of mixed light, they provide high color development possibilities. Furthermore, when the non-conductive material is mixed with phosphor, a specific light color is developed by incorporating the light emitted through the phosphor from the LED and the light wavelength of the phosphor.
4. The effective plated wire area for each LED can be easily made available simply by providing the lead frame and the conductive area to simplify the process of producing a PCB layer with a specific layout in the prior art, thus to effectively promote the acceptance level of production.

The prevent invention provides an improved structure of a LED package, and the application for a utility patent is duly filed accordingly. However, it is to be noted that that the preferred embodiments disclosed in the specification and the accompanying drawings are not limiting the present invention; and that any construction, installation, or characteristics that is same or similar to that of the present invention should fall within the scope of the purposes and claims of the present invention.

1. An LED package includes a heat slug to secure multiple light emitting diodes; two lead frames respectively extended to form conductive areas along opposite sides of the heat slug in a direction which parallels an arrangement of the light emitting diodes; and a non-conductive material connecting the heat slug and both lead frames by surrounding the sides of the heat slug in a form of a frame.

2. An LED package includes a heat slug to secure a high power chip LED; two lead frames respectively extended along opposite sides of the heat slug a conductive area; and a non-conductive material connecting the heat slug and both lead frames by surrounding the sides of the heat slug in a form of a frame.

3. The LED package of claim 1, wherein each said LED selectively contains one or a plurality of light emitting chip.

4. The LED package of claim 1, wherein said heat slug is generally covered up with an encapsulating material contained within said frame formed by the non-conductive material.

5. The LED package of claim 2, wherein said heat slug is generally covered up with an encapsulating material contained within said frame formed by the non-conductive material.

6. The LED package of claim 4, wherein said encapsulating material is mixed with phosphor.

7. The LED package of claim 1, wherein said heat slug is generally covered up with an encapsulating material, and a lens is further disposed on top of said encapsulating material.

8. The LED package of claim 2, wherein said heat slug is generally covered up with an encapsulating material, and a lens is further disposed on top of said encapsulating material.

9. The LED package of claim 7, wherein a refraction plane is formed to said lens in the traveling route of the light form the LED.

10. The LED package of claim 7, wherein a pin is formed at where both of said lens and said non-conductive material contact each other, and a recess to engage said pin is provided to said non-conductive material.

11. The LED package of claim 1, wherein said heat slug comprises an aluminum substrate material.

12. The LED package of claim 2, wherein said heat slug is related to an aluminum substrate material.

13. The LED package of claim 1, wherein said heat slug comprises a copper substrate material.

14. The LED package of claim 2, wherein said heat slug is related to a copper substrate material.

15. An LED package includes a heat slug to secure multiple light emitting diodes; two lead frames respectively extended along opposite sides of the heat slug to form conductive areas; and a non-conductive material connecting the heat slug and both lead frames by surrounding the sides of the heat slug in a form of a frame, wherein a pin is formed at where both of said lens and said non-conductive material contact each other, and a recess to engage said pin is provided to said non-conductive material.
